(19) United States
(12) Patent Application Publication
(10) Pub. No.: US 2010/0090341 A1
(43) Pub. Date: Apr. 15, 2010

(54) NANO-PATTERNED ACTIVE LAYERS FORMED BY NANO-IMPRINT LITHOGRAPHY

(75) Inventors: Fen Wan, Austin, TX (US); Frank Y. Xu, Round Rock, TX (US); Sidlgata V. Sreenivasan, Austin, TX (US); Shuqiang Yang, Austin, TX (US)

Correspondence Address: MOLECULAR IMPRINTS, PO BOX 81536, AUSTIN, TX, 78708-1536, US

(73) Assignees: MOLECULAR IMPRINTS, INC., Austin, TX (US); BOARD OF REGENTS, THE UNIVERSITY OF TEXAS SYSTEM, Austin, TX (US)

(21) Appl. No.: 12/578,286

(22) Filed: Oct. 13, 2009

Related U.S. Application Data
(60) Provisional application No. 61/105,127, filed on Oct. 14, 2008.
(60) Provisional application No. 61/107,366, filed on Oct. 22, 2008.
(60) Provisional application No. 61/106,204, filed on Oct. 17, 2008.

(51) Int. Cl. H01L 23/50; H01L 21/3205

(52) U.S. Cl. 257/749; 438/665; 257/E23.079; 257/E21.299

(57) ABSTRACT

Patterned active layers formed by nano-imprint lithography for use in devices such as photovoltaic cells and hybrid solar cells. One such photovoltaic cell includes a first electrode and a first electrically conductive layer electrically coupled to the first electrode. The first conductive layer has a multiplicity of protrusions and recesses formed by a nano-imprint lithography process. A second electrically conductive layer substantially fills the recesses and covers the protrusions of the first conductive layer, and a second electrode is electrically coupled to the second conductive layer. A circuit electrically connects the first electrode and the second electrode.

### CROSS-REFERENCE TO RELATED APPLICATIONS

This application claims the benefit under 35 U.S.C. §119(e)(1) of U.S. Provisional Patent Application Ser. Nos. 61/105,127, filed Oct. 14, 2008; 61/106,204 filed Oct. 17, 2008; and 61/107,366 filed Oct. 22, 2008, all of which are hereby incorporated by reference herein in their entirety.

### TECHNICAL FIELD

The present invention relates nano-patterned active layers formed by nano-imprint lithography.

### BACKGROUND

Nano-fabrication includes the fabrication of very small structures that have features on the order of 100 nanometers or smaller. One application in which nano-fabrication has had a sizeable impact is in the processing of integrated circuits. The semiconductor processing industry continues to strive for larger production yields while increasing the circuits per unit area formed on a substrate; therefore nano-fabrication becomes increasingly important. Nano-fabrication provides greater process control while allowing continued reduction of the minimum feature dimensions of the structures formed. Other areas of development in which nano-fabrication has been employed include biotechnology, optical technology, mechanical systems, and the like.

An exemplary nano-fabrication technique in use today is commonly referred to as imprint lithography. Exemplary imprint lithography processes are described in detail in numerous publications, such as U.S. Patent Application Publication No. 2004/0065976, U.S. Patent Application Publication No. 2004/0065252, and U.S. Pat. No. 6,936,194, all of which are hereby incorporated by reference herein.

An imprint lithography technique disclosed in each of the aforementioned U.S. patent application publications and patent includes formation of a relief pattern in a formable (polymerizable) layer and transferring a pattern corresponding to the relief pattern into an underlying substrate. The substrate may be coupled to a motion stage to obtain a desired positioning to facilitate the patterning process. The patterning process uses a template spaced apart from the substrate and the formable liquid applied between the template and the substrate. The formable liquid is solidified to form a rigid layer that has a pattern conforming to a shape of the surface of the template that contacts the formable liquid. After solidification, the template is separated from the rigid layer such that the template and the substrate are spaced apart. The substrate and the solidified layer are then subjected to additional processes to transfer a relief image into the substrate that corresponds to the pattern in the solidified layer.

### SUMMARY

In one aspect, a device includes a first electrode and a first electrically conductive layer formed by nano-imprint lithography and electrically coupled to the first electrode. The first conductive layer defines a multiplicity of protrusions and recesses. A second electrically conductive layer substantially fills the recesses and covers the protrusions of the first conductive layer. A second electrode is electrically coupled to the second conductive layer, and a circuit electrically connecting the first electrode and the second electrode.

In another aspect, a nano-imprint lithography method includes forming a first electrically conductive layer having a multiplicity of protrusions and recesses with a nano-imprint lithography process. A first electrode is electrically coupled to the first conductive layer. A second electrically conductive layer is deposited on the first conductive layer, and a second electrode is electrically coupled to the second conductive layer. The first electrode and the second electrode are electrically connected. Depositing may include substantially filling the recesses in the first conductive layer and covering the protrusions in the first conductive layer with the second conductive layer

In some implementations, one of the electrodes reflects ultraviolet light and one of the electrodes is substantially transparent to ultraviolet light. A spacing between the protrusions in the first conductive layer may be less than about 20 nm, less than about 10 nm, or less than about 5 nm. In some cases, a spacing between the protrusions in the first conductive layer is between about 5 nm and about 20 nm, or between about 5 nm and about 10 nm. A length of the protrusions in the first conductive layer is at least about 50 nm, at least about 100 nm, at least about 200 nm, at least about 300 nm, at least about 400 nm, or at least about 500 nm. A length of the protrusions in the first conductive layer may be less than about 1000 nm. A ratio of the length of the protrusions to the spacing between the protrusions is at least about 5, at least about 10, at least about 20, at least about 30, at least about 40, at least about 50, or at least about 100. A ratio of the length of the protrusions to the spacing between the protrusions may be between about 5 and about 100.

In some implementations, the first conductive layer or the second conductive layer includes a conductive polymer composition. The polymer composition may be organic or an organic-inorganic hybrid. An organic polymer may be conjugated or non-conjugated. The conductive polymer composition may include a polymer selected from the group consisting of polyacetylene, polypyrrole, polythiophene, polyaniline, polyfluorene, [6,6]-phenyl C₆₁-butyric acid methyl ester, and combinations and derivatives thereof. In some cases, forming the first electrically conductive layer with a nano-imprint lithography process includes ultraviolet curing of an organic conductive polymer to form the electron donor layer.

In some implementations, the first conductive layer is an electron acceptor layer and the second conductive layer is an electron donor layer. In some implementations, the first conductive layer is an electron donor layer and the second conductive layer is an electron acceptor layer. The second conductive layer may be formed by electrochemical deposition. In some cases, the second conductive layer is formed by vapor deposition, spin coating, dip coating, or the like.

In some implementations, forming the first conductive layer includes solidifying a conductive polymerizable material on the first electrode. Depositing the second conductive layer may include electrochemically depositing the second conductive layer in the recesses and on the protrusions of the first conductive layer. Depositing the second conductive layer comprises substantially filling the recesses such that the filled recesses are substantially without voids.

In one aspect, a patterned layer including a multiplicity of protrusions is formed on a substrate. A conductive polymer is electrodeposited on the patterned layer, and the patterned layer is dissolved to yield a conductive layer with a multiplicity of recesses, wherein the recesses are complementary to the protrusions of the patterned layer.

In one aspect, a nano-patterned layer is formed on a substrate with a nano-imprint lithography process. The nano-patterned layer includes protrusions and/or recessions. A conducting polymer is electrodeposited between the protrusions, and the nanoporous patterned layer is substantially removed to yield a nanoporous conducting layer including conducting polymer. In some implementations, the substrate comprises silicon. The nanoporous metal layer may include a metal oxide, such as zinc oxide, aluminum oxide, or a mixture thereof. The conductive polymer may include a polymer selected from the group consisting of polyacetylene, polypyrrole, polythiophene, polyaniline, polyfluorene, [6,6]-phenyl C₆₁-butyric acid methyl ester, and combinations and derivatives thereof.

In one aspect, a nanoporous patterned layer is formed on a substrate with a nano-imprint lithography process. The nanoporous patterned layer includes protrusions. A portion of the patterned layer is coated with a conductive metal. A conductive polymer is electrodeposited on the nanoporous patterned layer, and the nanoporous patterned layer is substantially removed to form a conducting polymer layer on the conductive metal layer.

In some implementations, coating the portion of the patterned layer with the conductive metal includes coating a portion of the protrusions with the conductive metal. Coating the portion of the patterned layer with the conductive metal may include coating a portion of the protrusions and the recesses between the protrusions with the conductive metal. The conductive polymer layer may include nanowires or nanotubes.

In an aspect, a nanoporous patterned layer is formed by a nano-imprint lithography method on a substrate. The nanoporous patterned layer includes protrusions. A conductive polymer is electrodeposited on the nanoporous patterned layer. In some implementations, the conductive polymer includes polythiophene or other polymers described herein. The nanoporous patterned layer may include n-type silicon.

In an aspect, a patterned layer is formed of a conductive material on a substrate by an imprint lithography method. The patterned layer includes protrusions. A portion of the patterned layer between the protrusions is coated with an insulating material, and a conductive polymer is electrodeposited on the protrusions of the patterned layer.

In some implementations, the electrodeposition occurs in the presence of an electrolyte, and the insulating material is substantially insoluble in the electrolyte. The insulating material may be substantially removed from between the protrusions after electrodepositing the conducting polymer.

In one aspect, a device includes a first electrode, an electron acceptor layer formed by nano-imprint lithography electrically coupled to the first electrode, the electron acceptor layer comprising recesses, an electron donor layer electrochemically deposited in the recesses of the electron acceptor layer, a second electrode electrically coupled to the electron donor layer, and a circuit electrically connecting the first electrode and the second electrode.

In one aspect, forming a photovoltaic device includes forming a patterned electron acceptor layer with a nano-imprint lithography process. The patterned electron acceptor layer includes recesses. An electron donor layer is formed on the patterned electron acceptor layer. Forming the electron donor layer includes electrochemically depositing an electron donor in the recesses of the electron acceptor layer. A first electrode is electrically coupled to the electron acceptor layer. A second electrode is electrically coupled to the electron donor layer. The first electrode and the second electrode are electrically connected.

In some implementations, the first electrode is transparent. The first electrode may include indium tin oxide. The electron acceptor layer may include silicon. A spacing between recesses in the electron acceptor layer may be less than about 20 nm, and a depth of the recesses in the electron acceptor layer is at least about 50 nm. A ratio of the depth of the recesses to a spacing between the recess is at least about 5, at least about 10, or at least about 20. The electron donor layer may include a conductive polymer. The conductive polymer may be selected from the group consisting of polyacetylene, polypyrrole, polythiophene, polyaniline, polyfluorene, and combinations and derivatives thereof. In some cases, the electron donor layer is formed from a liquid polymerizable composition including a solvent, an electrolyte, or both. The second electrode may be reflective, and may include aluminum, zinc, cadmium, or other low work function metal.

In some implementations, electrochemically depositing the electron donor includes substantially filling the recesses in the electron acceptor from the bottom up. Electrochemically depositing the electron donor may include substantially filling the recesses such that the filled recesses are substantially without voids. Forming the electron donor layer may include immersing the electron acceptor layer in a conductive polymerizable liquid.

In one aspect, a device includes a first electrode, an electron donor layer including recesses formed by nano-imprint lithography and electrically coupled to the first electrode, an electron acceptor layer deposited in the recesses of the electron donor layer, a second electrode electrically coupled to the electron acceptor layer, the second electrode including a conducting polymer, and a circuit electrically connecting the first electrode and the second electrode.

In another aspect, forming a photovoltaic cell includes forming a patterned electron donor layer including recesses with a nano-imprint lithography process, forming an electron acceptor layer on the patterned electron donor layer, wherein forming the electron acceptor layer includes depositing an electron acceptor in the recesses of the electron donor layer, forming a first electrode electrically coupled to the electron donor layer, the first electrode including a conducting polymer, forming a second electrode electrically coupled to the electron acceptor layer, and electrically connecting the first electrode and the second electrode.

In some implementations, the first electrode is transparent. The first electrode may include a conductive polymer. Forming the first electrode may include spin coating a polymerizable liquid on the electron donor layer. The second electrode is reflective. The second electrode may include PEDOT:PSS. Depositing the electron acceptor may include electrochemically depositing the electron acceptor in the recesses of the electron donor layer. he electron acceptor layer may include [6,6]-phenyl C₆₁-butyric acid methyl ester. The electron donor layer may include a conducting polymer selected from the group consisting of polyacetylene, polypyrrole, polythiophene, polyaniline, polyfluorene, and combinations and derivatives thereof. The electron donor layer may be formed from a liquid polymerizable composition in the absence of a solvent. The electron donor layer is a may be a photopolymerization product of a polymerizable composition including a conducting polymer precursor and a cationic photoinitiator. Photopolymerization may include UV irradiation at ambient temperature.

A spacing between recesses in the electron donor layer may be less than about 20 nm. A depth of the recesses in the electron donor layer may be at least about 50 nm. A ratio of a depth of the recesses to a spacing between the recesses is at least about 5, at least about 10, at least about 20, or at least about 30.

### BRIEF DESCRIPTION OF THE DRAWINGS

FIG. 1 illustrates a simplified side view of a lithographic system in accordance with an embodiment of the present invention.

FIG. 2 illustrates a simplified side view of the substrate shown in FIG. 1 having a patterned layer positioned thereon.

FIGS. 3A-3C depict the formation of a nano-patterned active layer for a device such as a photovoltaic cell.

FIGS. 4A-4B illustrate cross-sectional views of a photovoltaic cell with an active layer formed by nano-imprint lithography.

FIG. 5 illustrates electrochemical deposition of a conductive polymer in recesses formed by nano-imprint lithography.

FIGS. 6A-6D illustrate formation of a conductive nanoporous film by a process including nano-imprint lithography and electrodeposition.

FIG. 7A illustrates formation of nanotubes by electropolymerization.

FIG. 7B illustrates formation of nanowires by electropolymerization.

FIGS. 8A-8C illustrate electrodeposition of a conducting polymer in a nanoporous structure formed by nano-imprint lithography.

FIGS. 9A-9C illustrate electrodeposition of a conductive polymer on exposed conductive regions of a patterned surface.

### DETAILED DESCRIPTION

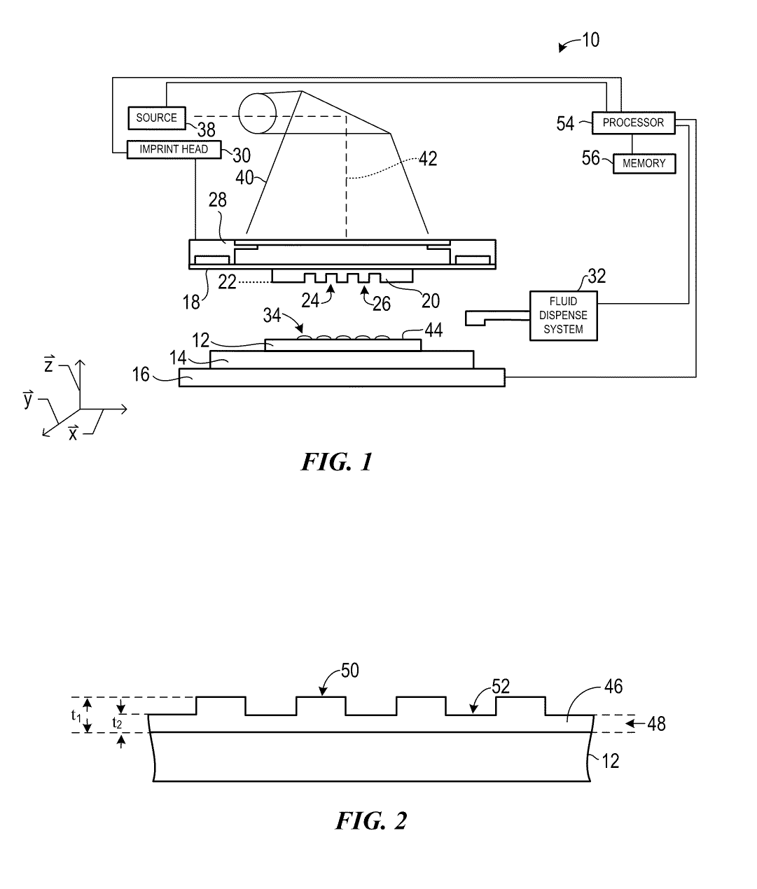

Referring to FIG. 1, illustrated therein is a lithographic system 10 used to form a relief pattern on substrate 12. Substrate 12 may be coupled to substrate chuck 14. As illustrated, substrate chuck 14 is a vacuum chuck. Substrate chuck 14, however, may be any chuck including, but not limited to, vacuum, pin-type, groove-type, electromagnetic, and/or the like. Exemplary chucks are described in U.S. Pat. No. 6,873,087, which is hereby incorporated by reference herein.

Substrate 12 and substrate chuck 14 may be further supported by stage 16. Stage 16 may provide motion about the x-, y-, and z-axes. Stage 16, substrate 12, and substrate chuck 14 may also be positioned on a base (not shown).

Spaced-apart from substrate 12 is a template 18. Template 18 generally includes a mesa 20 extending therefrom towards substrate 12, mesa 20 having a patterning surface 22 thereon. Further, mesa 20 may be referred to as mold 20. Template 18 and/or mold 20 may be formed from such materials including, but not limited to, fused-silica, quartz, silicon, organic polymers, siloxane polymers, borosilicate glass, fluorocarbon polymers, metal, hardened sapphire, and/or the like. As illustrated, patterning surface 22 comprises features defined by a plurality of spaced-apart recesses 24 and/or protrusions 26, though embodiments of the present invention are not limited to such configurations. Patterning surface 22 may define any original pattern that forms the basis of a pattern to be formed on substrate 12.

Template 18 may be coupled to chuck 28. Chuck 28 may be configured as, but not limited to, vacuum, pin-type, groove-type, electromagnetic, and/or other similar chuck types. Exemplary chucks are further described in U.S. Pat. No. 6,873,087, which is hereby incorporated by reference herein. Further, chuck 28 may be coupled to imprint head 30 such that chuck 28 and/or imprint head 30 may be configured to facilitate movement of template 18.

System 10 may further comprise a fluid dispense system 32. Fluid dispense system 32 may be used to deposit polymerizable material 34 on substrate 12. Polymerizable material 34 may be positioned upon substrate 12 using techniques such as drop dispense, spin-coating, dip coating, chemical vapor deposition (CVD), physical vapor deposition (PVD), thin film deposition, thick film deposition, and/or the like. Polymerizable material 34 may be disposed upon substrate 12 before and/or after a desired volume is defined between mold 20 and substrate 12 depending on design considerations. Polymerizable material 34 may comprise a monomer as described in U.S. Pat. No. 7,157,036 and U.S. Patent Application Publication No. 2005/0187339, all of which are hereby incorporated by reference herein.

Referring to FIGS. 1 and 2, system 10 may further comprise an energy source 38 coupled to direct energy 40 along path 42. Imprint head 30 and stage 16 may be configured to position template 18 and substrate 12 in superimposition with path 42. System 10 may be regulated by a processor 54 in communication with stage 16, imprint head 30, fluid dispense system 32, and/or source 38, and may operate on a computer readable program stored in memory 56.

Either imprint head 30, stage 16, or both vary a distance between mold 20 and substrate 12 to define a desired volume therebetween that is filled by polymerizable material 34. For example, imprint head 30 may apply a force to template 18 such that mold 20 contacts polymerizable material 34. After the desired volume is filled with polymerizable material 34, source 38 produces energy 40, e.g., broadband ultraviolet radiation, causing polymerizable material 34 to solidify and/or cross-link conforming to shape of a surface 44 of substrate 12 and patterning surface 22, defining a patterned layer 46 on substrate 12. Patterned layer 46 may comprise a residual layer 48 and a plurality of features shown as protrusions 50 and recessions 52, with protrusions 50 having a thickness t₁ and residual layer 48 having a thickness t₂.

The above-described system and process may be further implemented in imprint lithography processes and systems referred to in U.S. Pat. No. 6,932,934, U.S. Patent Application Publication No. 2004/0124566, U.S. Patent Application Publication No. 2004/0188381, and U.S. Patent Application Publication No. 2004/0211754, each of which is hereby incorporated by reference herein.

Nano-imprint lithography may be used to form an active layer of a photovoltaic cell. In an embodiment, an active layer of a photovoltaic cell may be formed by solidifying a polymerizable composition to form a patterned active layer on a substrate as described above with respect to FIGS. 1 and 2. The patterned active layer may be an electron donor layer or an electron acceptor layer. Nano-imprint lithography may be used to achieve a desired spacing between electron donor material and electron acceptor material.

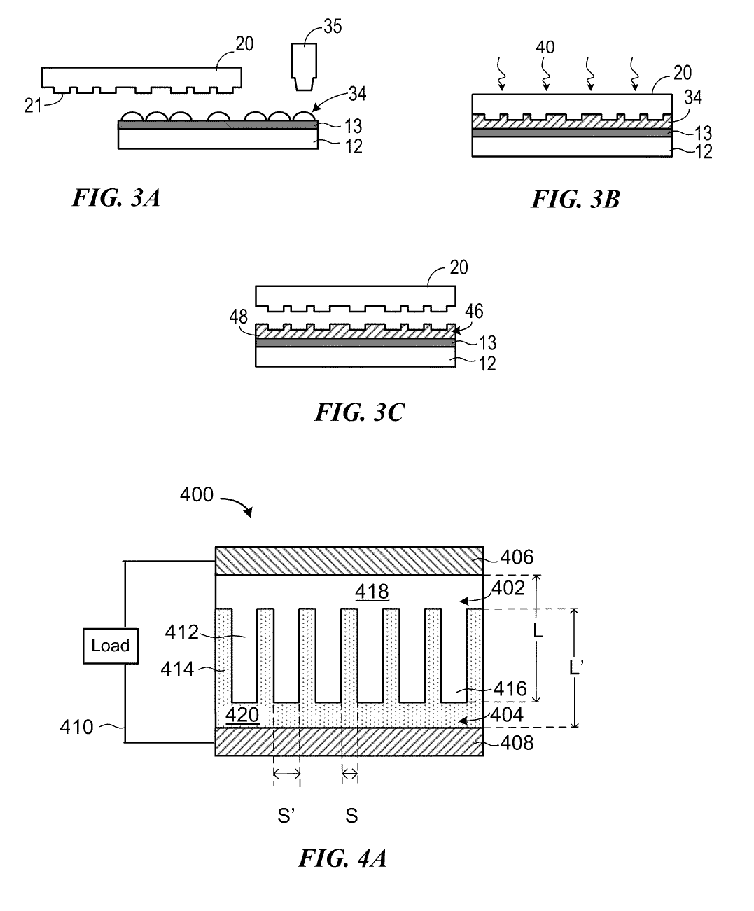

FIGS. 3A-3C depict the formation of a nano-patterned conductive polymer for a device such as an photovoltaic cell. The photovoltaic cell may be an organic photovoltaic cell or hybrid solar cell. As depicted in FIG. 3A, transparent mold 20, which may have release layer 21, is oriented with respect to substrate 12. One or more layers 13 may be present on the substrate. Layer 13 may be, for example, an adhesion layer, a hard mask layer, or the like. A polymerizable composition 34 may be applied to the substrate 12 (or additional layer 13) using, for example, dispenser 35 to form a multiplicity of drops on the substrate. The polymerizable composition 34 may include one or more polymer precursors curable with ultraviolet light.

In FIG. 3B, polymerizable composition 34 is contacted with mold 20. Mold 34 is illuminated with UV radiation 40 to solidify the polymerizable material. Polymerization may occur at room temperature and atmospheric pressure. After polymerizable composition 34 is solidified, mold 20 is separated from substrate 12, as shown in FIG. 3C, leaving a nano-patterned layer 46 (with residual layer 48) adhered to substrate 12 (or to additional layer 13).

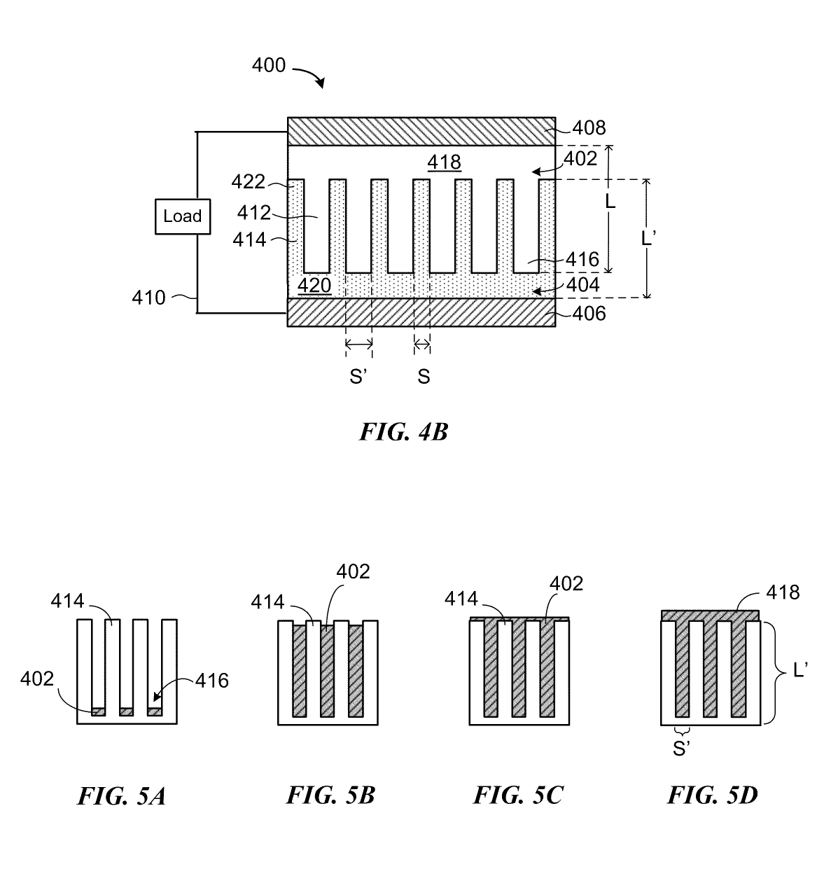

FIG. 4A illustrates a cross-sectional view of a portion of a photovoltaic cell 400. Photovoltaic cell 400 includes electron donor layer 402 and electron acceptor layer 404 sandwiched between transparent electrode 406 and reflective electrode 408. Electron donor layer 402 and electron acceptor layer 404 may include an electrically conductive polymer composition. The conductive polymer composition may be organic (e.g., carbon-containing and substantially non-metal-containing) or an organic-inorganic hybrid (e.g., carbon-containing and metal-containing). The conductive polymer may be conjugated or non-conjugated.

Electrical circuit 410 is formed between transparent electrode 406 and reflective electrode 408. Reflective electrode 408 is able to reflect electromagnetic radiation present in solar energy and may include, for example, aluminum, zinc, cadmium, and other low work function metals. Transparent electrode 406 is substantially transparent to electromagnetic radiation present in solar energy. Transparent electrode 406 may function as an electron collection electrode. In an example, transparent electrode 402 is formed of glass coated with indium tin oxide. In another example, transparent electrode 402 may include a conductive polymer such as poly(3,4-ethylenedioxythiophene) poly(styrenesulfonate) (PEDOT:PSS).

An electrode made of doped conductive polymer with high conductivity, high transparency to electromagnetic radiation, and a high work function may be used as an anode in organic photovoltaic cells including organic and organic-inorganic hybrid cells. The conductive polymer electrode is non-rigid, and can be used in place of a more rigid electrode with a lower work function, such as glass coated with indium tin oxide. Conductive polymers that may be used as electrodes in photovoltaic cells described herein include, for example, PEDOT:PSS and other doped conjugated polymers with similar properties. In an example, CLEVIOS PH500 (available from H.C. Starck, Germany), is a PEDOT:PSS that can achieve a sheet resistance of less than 500 ohm/square and a transmission of 75% at a thickness of 200 nm with one or more selected polar solvents with a high boiling point (e.g., ethylene glycol).

Advantages of using conductive (e.g., conjugated) polymers as electrodes for solar cells may include a high work function, which allows efficient hole extraction. Other advantages include processability, which allows better control of surface planarity, and increased adhesion between layers (e.g., between polymer layers with similar chemical properties). Electrodes formed from conductive polymers are advantageously flexible (i.e., not rigid), allowing implementation in a variety of configurations, including tandem cell arrays, V-shaped cells, and the like, which may be used to enhance power conversion efficiency. Additionally, fabrication costs for electrodes formed from conductive polymers are advantageously less, than for electrodes formed from more rigid, difficult to process materials.

Use of a conductive polymer as the anode in solar cells with a nano-patterned active layer allows fabrication of solar cells from the anode and the cathode. That is, the active layer may be formed on the cathode (the reflective electrode) and the anode formed on the active layer, or the active layer may be formed on the anode (the transparent electrode), and the cathode formed on the active layer. One or more conductive polymers or a mixture thereof can be deposited on the first active layer by spin coating, inkjet printing, and the like, to form a conductive, transparent electrode.

Referring again to FIG. 4A, protrusions 412 of electron donor layer 402 are interleaved with protrusions 414 of electron acceptor layer 404, with a width of protrusions 414 defining a spacing S between protrusions 412, and a width of protrusions 412 defining a spacing S′ between protrusions 414. In some embodiments, the protrusions 412 and 414 are substantially equal in width, and spacings S and S′ are substantially the same.

Spacings S and S′ may be selected to be on the order of the distance electrons and holes are able to diffuse through either the electron donor material or the electron acceptor material, such that electrons are transferred efficiently from the electron donor to the electron acceptor and the holes in the photovoltaic cell are able to diffuse from an acceptor layer to a donor layer. For some electron donor and electron acceptor materials, the distance electrons are able to diffuse through the material is less than about 20 nm (e.g., between about 5 nm and about 20 nm, or between about 10 nm and about 20 nm).

A depth of the recesses between protrusions 412 and 414, or a length L of protrusions 412 and a length L′ of protrusions 414, are selected such that solar energy is efficiently captured. L and L′ may be, for example, at least about 50 nm, at least about 100 nm, at least about 200 nm, at least about 300 nm, or at least about 400 nm. In some cases, L and L′ are substantially the same. In photovoltaic cell 400, with S substantially equal to S′ and L substantially equal to L′, a ratio of L/S may be at least about 5, at least about 10, at least about 20, or greater. Feature depths needed to absorb a sufficient quantity of solar energy in organic solar cells is described by Günes et al. in “Conjugated polymer-based organic solar cells,” Chemical Reviews, 107(4) 2007, pp. 1324-1338, which is incorporated by reference herein.

As shown in FIG. 4A, residual layer 420 of electron acceptor layer 404 is in contact with reflective electrode 408 and residual layer 418 of electron donor layer 402 is in contact with transparent electrode 406. This may be achieved by forming a patterned electron acceptor layer 404 on a reflective electrode 408 or by forming a patterned electron donor layer 402 on transparent electrode 406. In some cases, however, as shown in FIG. 4B, electron donor layer 402 is in contact with reflective electrode 408, and electron acceptor layer 404 is in contact with transparent electrode 406. This may be achieved by forming a patterned electron donor layer 402 on a reflective electrode 408 or by forming a patterned electron acceptor layer 404 on transparent electrode 406. In some cases, rather than forming a pattern including protrusions and rejections in, for example, an electron acceptor layer or an electron donor layer, a multiplicity of recesses may be formed (e.g., etched) in the layer.

In an example, patterned electron acceptor layer 404 may be formed by a nano-imprint lithography process on reflective electrode 408. Electron acceptor layer 404 may be formed by depositing polymerizable electron acceptor material on reflective electrode 408 and forming protrusions and recesses as described with respect to FIGS. 3A-3C. In some cases, electron acceptor layer 404 is formed by using a nano-imprint lithography process to etch a desired pattern in an electron acceptor material, such as n-type silicon. Electron donor material may be deposited in recesses 416 of electron acceptor layer 404 (e.g., between or around protrusions 414 of the electron acceptor layer) to form “protrusions” 412. Electron donor material may also be deposited on top of the protrusions 414 of the electron acceptor layer to form “residual layer” 418. Transparent electrode 406 may be formed on top of layer 418.

Electrochemical polymerization (or electropolymerization) may be used to deposit one or more donor materials in recesses 416 in electron acceptor layer 404 (e.g., between protrusions 414 in the electron acceptor layer) to form “protrusions” 412. The donor material may include a conductive polymer. In this process, a polymerizable liquid may be placed in the recesses in the electron acceptor layer 404. In some cases, the recesses are substantially filled with the polymerizable liquid. The polymerizable liquid may include monomers capable of forming conductive polymers with a low bandgap, such as polyacetylene, polypyrrole, polythiophene, polyaniline, polyfluorene, and any combination or derivative thereof. In an example, the polymerizable liquid includes 3-hexylthiophene, and the conductive polymer includes poly-3-hexylthiophene.

The polymerizable liquid used to form the electron donor layer may include a solvent, an electrolyte, one or more additional additives, or a combination thereof. Examples of solvents include chlorobenzene, acetonitrile, dichlorobenzene, water, and the like. Examples of electrolytes include sulfuric acid, hypochlorite salts, and the like. If a solvent is used, it may be selected to be compatible (e.g., miscible) with the chosen monomers. Some monomers, for example, thiophene, may be used a small amount of solvent or with no solvent.

In some embodiments, electron acceptor recesses are filled with polymerizable liquid by immersing the acceptor layer in a polymerizable liquid. The electron acceptor base may be used as the working electrode. During electrochemical oxidation, the conductive polymer is galvanostatically deposited in the nano-sized openings in the electron acceptor layer 404. Deposition of the conductive polymer to form electron donor layer 402 is achieved beginning at the bottom of recesses 416 in the electron acceptor layer 404, as shown by the progression in FIGS. 5A-D. Electrodeposition is described by Hillman et al. in “Electrochemistry of electroactive materials,” Electrochimica Acta, 53(11) 3742-3743 (2008), which is incorporated herein by reference.

Deposition of the donor material from the bottom of the well up allows the recesses in the acceptor layer to be filled with donor material at an L/S ratio of up to about 400 substantially without the formation of voids in the donor material. With the small spacing S between acceptor and donor (e.g., about 5-20 nm), and the substantial absence of voids in the acceptor material and the donor material, the resulting photovoltaic cell demonstrates high conversion efficiency.

Referring again to FIGS. 3A-C, forming a patterned active layer by imprint lithography may include photopolymerizing a polymerizable composition including conductive polymer precursors and a cationic photoinitiator to form an electron donor layer. The cationic photoinitiators may be soluble in the polymer precursors (e.g., monomers). Thus, photopolymerization may be performed in the absence of a solvent. In some cases, photopolymerization may occur in the presence of a solvent such as, for example, tetrahydrofuran. Examples of conductive polymer precursor/cationic photoinitiator combinations include pyrrole and iron-arene salts, thiophene and iodonium salts, and the like.

Nano-imprinting of conductive polymer (e.g., electron donor or p-type) materials with cationic photoinitiators may be achieved by UV curing at room temperature. For example, p-type materials for organic light emitting devices (OLEDs) and organic photovoltaic (OPV) cells can be fabricated by UV curing of polymerizable compositions including conducting (e.g., conjugated) polymer precursors and a cationic photoinitiator. This process allows the formation, through nano-imprint lithography, of a nano-patterned layer including features (e.g., nano-pillars, recesses, and the like) with a spacing of about 5-20 nm, or on the order of the diffusing distance of charge carriers or excitons in the conductive polymer.

FIG. 4B depicts an active layer formed by nano-imprint lithography, sandwiched between a reflective electrode 408 and a transparent electrode 406. The p-type material of the electron donor layer 402 may include polythiophene or other conductive polymers with a low bandgap. The n-type layer of the electron acceptor layer 404 may include [6,6]-phenyl C₆₁-butyric acid methyl ester (PCBM) or other n-type materials. The reflective electrode 408 may include, for example, aluminum. The transparent electrode 406 may include a conductive polymer such as, for example, poly(3,4-ethylenedioxythiophene) poly(styrenesulfonate) (PEDOT:PSS).

Recesses 422 in the electron donor (p-type) material may be spaced about 20 nm apart or less (e.g., about 5-20 nm apart, or about 10-20 nm apart). The recesses in the p-type material may be substantially filled with electron acceptor (n-type) material that has been, for example, spin coated, electrochemically deposited, or vapor deposited on the electron donor material. The n-type material may substantially fill the recesses in the p-type material and form a layer over the electron donor material. A reflective electrode may be formed to substantially cover the electron acceptor material. A transparent electrode may be formed on the electron donor layer. An electrical circuit may be formed between the two electrodes. A depth of the n-type material may be, for example, less than a micron, but at least about 50 nm. A ratio of the depth of the n-type material to the spacing between the p-type recesses may be at least about 5.

In some embodiments, a patterned layer on a conductive substrate may be used as working electrode to guide the growth of conductive polymers (e.g., polypyrrole, polythiophene, etc.) through electropolymerization. The polymer may grow on a protrusion or in a recess, depending on the conductivity of the protrusions and recesses. That is, polymerization may occur in the area with less electrical resistance, defining nanotubes, nanopillars, and the like.

After electropolymerization, the patterned layer, or template, may be removed by treating with a suitable solvent, leaving holes to be filled with an electron acceptor, such as PCBM. For example, a patterned metal oxide layer may be removed by treating with acid. In some cases, however, the template may be retained as a portion of the device. For example, if a porous silicon wafer is used as a template, it can serve as electron acceptor, with electropolymerized conductive polymer such as polythiophene as the electron donor. When polymers are grown on protrusions, templates may also be left intact.

Fabrication of photovoltaic cells by imprint lithography using electropolymerization to directly deposit nanostructured conductive polymers reduces handling of the polymerizable material and allows use of a range of conductive polymers, including conductive polymers soluble in common solvents. This method may be implemented without spin coating, and thus without requirements of spin coating processes, including a wettable surface. Additionally, the resolution or spacing between electron donor portions and electron acceptor portions is advantageously governed by the dimensions of the template formed by nano-imprint lithography, such that high L/S ratios can be achieved.

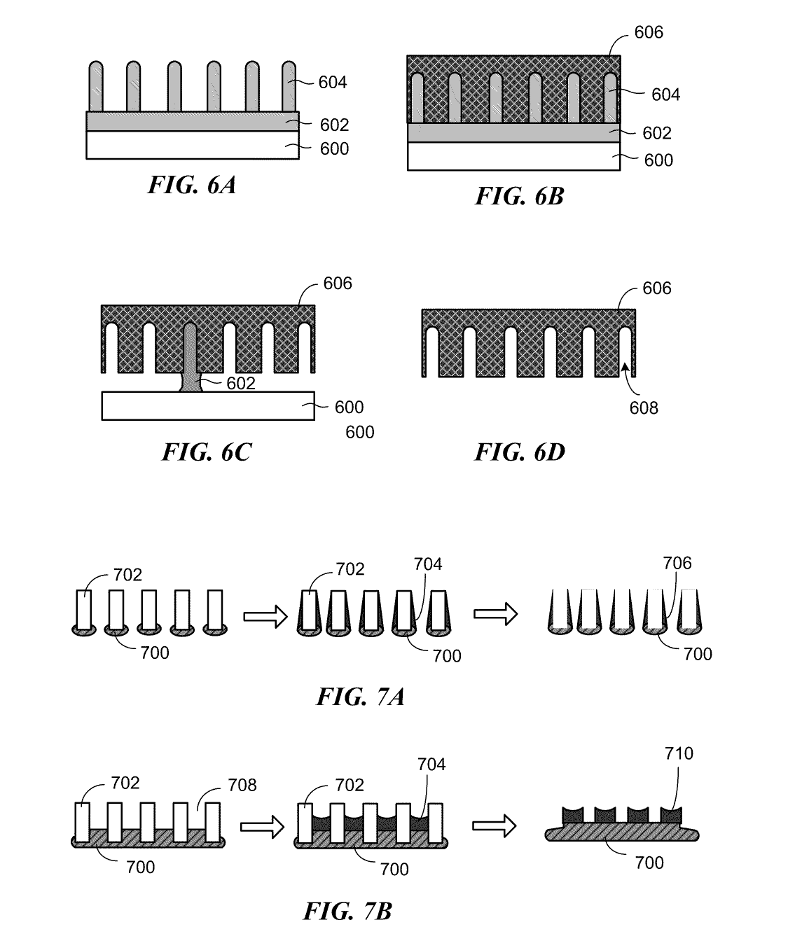

When nanoporous templates (e.g., patterned layers with nano-sized protrusions and recesses) with different conductivities in recesses and protrusions are used as working electrodes to electrochemically polymerize conductive polymer to define the nanostructure of active materials in organophotovoltaic (OPV) cells, the cells provide high power conversion efficiency and are relatively inexpensive to produce. This method may also be used to fabricate other devices, including other microelectronic devices such as organic light-emitting diodes (OLEDs). Examples of the use of patterned layers or templates formed by nano-imprint lithography to form conductive polymer structures are shown in FIGS. 6-9.

FIGS. 6A-6C illustrate formation of a conductive layer with recesses with a nano-imprint lithography process. As illustrated in FIG. 6A, a patterned layer 602 with protrusions 604 may be formed by a nano-imprint lithography process on a substrate 600. Patterned layer 602 may include, for example, aluminum oxide, zinc oxide, titanium oxide, silicon oxide, or the like. Substrate 600 may be a silicon substrate. In FIG. 6B conductive polymer 606 is electropolymerized to fill the recesses in the patterned layer and cover the nano-structures 604. Conductive polymer 606 may include, for example, polypyrrole. FIG. 6C illustrates dissolution of the patterned layer, and thus separation of the patterned polymerized layer 606 from the substrate 600. Recesses 608, defined by protrusions 604, remain in the conductive polymer layer 606. In an example, an acid (e.g., phosphoric acid), may be used to dissolve the patterned layer 602. In some cases, solvents other than acid may be used to dissolve the patterned layer 602. The resulting conductive thin film 606 is shown in FIG. 6D. Conductive thin film 606, with recesses 608, may be referred to as a nanoporous conductive film, or a nanoporous thin film.

FIGS. 7A and 7B illustrate formation of nanotubes and nanowires by electropolymerization. Formation of nanotubes and nanowires is described by Cho et al. in “Fast Electrochemistry of Conductive Polymer Nanotubes: Synthesis, Mechanism, and Application,” Acc. Chem. Res., 2008, 41(6), pp 699-707, which is hereby incorporated by reference.

As shown in FIG. 7A, metal 700 (e.g., gold), may be coated on protrusions 702 of a patterned layer. A conductive polymer 704 may be electropolymerized proximate the metal, for example, along the surface of the protrusions 702. The conductive polymer 704 may be, for example, PEDOT. When the patterned layer is removed (e.g., dissolved, as shown in FIG. 6C), the conductive polymer 704 remains in the form of nanotubes 706.

As shown in FIG. 7B, recesses 708 between protrusions 702 of a patterned layer may be filled with a metal 700 (e.g., gold). A conductive polymer 704 may be electrodeposited on the metal 700, between protrusions 702 of the template. When the template is removed (e.g., dissolved, as shown in FIG. 6C), the conductive polymer remains in the form of nanowires 710.

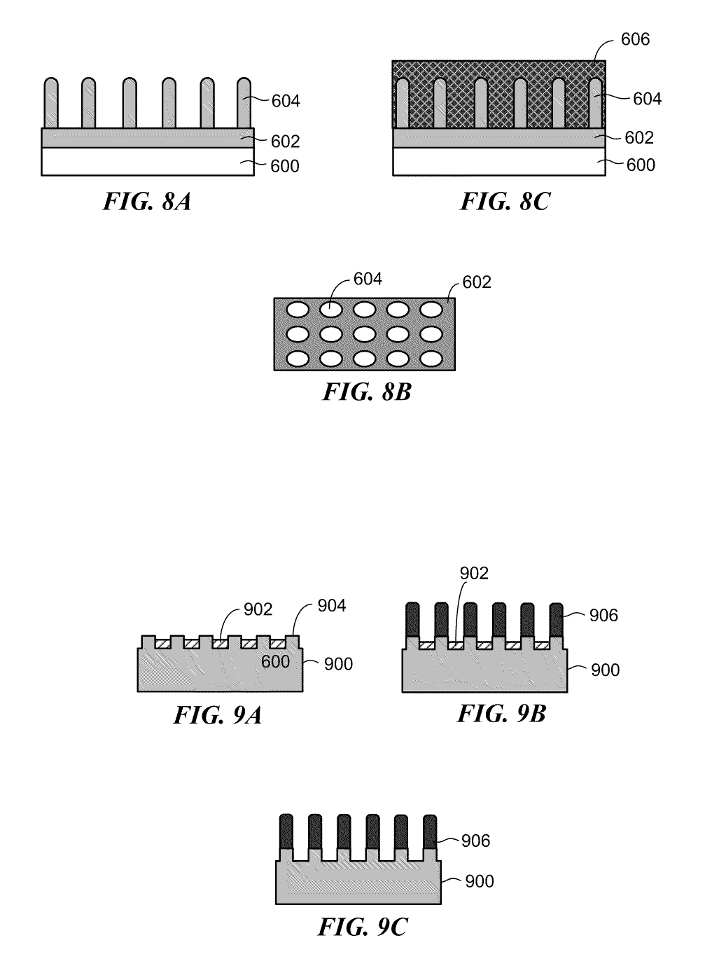

FIGS. 8A-8D illustrate electrodeposition of a conductive polymer in a patterned (e.g., nanoporous) structure formed by nano-imprint lithography. FIG. 8A shows a patterned layer 602 with protrusions 604. A top view of patterned layer 602, shown in FIG. 8B, shows the nanoporous structure of the patterned layer. The patterned layer 602 may be formed from, for example, an inorganic semiconductor, such as n-type silicon. A conductive polymer, such as polythiophene, may be electrodeposited on the protrusions 604, filling the recesses between the protrusions to form conductive layer 606, as shown in FIG. 8B.

As illustrated in FIGS. 9A-C, a patterned conducting layer may be formed through nano-imprint lithography. The layer may include gold, for example. As shown in FIG. 9A, an Insulating material 902 may be deposited between protrusions 904 in gold layer 900. The insulating layer may be, for example, wax, or any other insulating material that is substantially insoluble in the electrolyte used for electrodeposition. As shown FIG. 9B, conductive polymer 906 may be electrodeposited on the exposed protrusions 904. In FIG. 9C, the insulating material 902 may be dissolved to expose the conductive recesses 908 between protrusions 904. In some cases, however, the insulating material may be allowed to remain.

Further modifications and alternative embodiments of various aspects will be apparent to those skilled in the art in view of this description. Accordingly, this description is to be construed as illustrative only. It is to be understood that the forms shown and described herein are to be taken as examples of embodiments. Elements and materials may be substituted for those illustrated and described herein, parts and processes may be reversed, and certain features may be utilized independently, all as would be apparent to one skilled in the art after having the benefit of this description. Changes may be made in the elements described herein without departing from the spirit and scope as described in the following claims.

What is claimed is:

1. A device comprising:
a first electrode;
a first electrically conductive layer formed by nano-imprint lithography and electrically coupled to the first electrode, the first conductive layer defining a multiplicity of protrusions and recesses;
a second electrically conductive layer substantially filling the recesses and covering the protrusions of the first conductive layer;
a second electrode electrically coupled to the second conductive layer; and
a circuit electrically connecting the first electrode and the second electrode.

2. The device of claim 1, wherein one of the electrodes reflects ultraviolet light and one of the electrodes is substantially transparent to ultraviolet light.

3. The device of claim 1, wherein a spacing between the protrusions in the first conductive layer is less than about 20 nm.

4. The device of claim 1, wherein a length of the protrusions in the first conductive layer is at least about 50 nm.

5. The device of claim 1, wherein a ratio of the length of the protrusions to the spacing between the protrusions is at least about 5.

6. The device of claim 1, wherein the first conductive layer or the second conductive layer comprises a conductive polymer.

7. The device of claim 1, wherein the first conductive layer is an electron acceptor layer and the second conductive layer is an electron donor layer, or the first conductive layer is an electron donor layer and the second conductive layer is an electron acceptor layer.

8. The device of claim 1, wherein the second conductive layer is formed by electrochemical deposition.

9. The device of claim 1, wherein the first conductive layer or the second conductive layer comprises a conductive polymer composition.

10. The device of claim 9, wherein the conductive polymer composition comprises a polymer selected from the group consisting of polyacetylene, polypyrrole, polythiophene, polyaniline, polyfluorene, [6,6]-phenyl C₆₁-butyric acid methyl ester, and combinations and derivatives thereof.

11. A nano-imprint lithography method comprising:
forming a first electrically conductive layer with a nano-imprint lithography process, the first conductive layer having a multiplicity of protrusions and recesses;
depositing a second electrically conductive layer on the first conductive layer, wherein depositing comprises substantially filling the recesses in the first conductive layer and covering the protrusions in the first conductive layer with the second conductive layer;
electrically coupling a first electrode to the first conductive layer;
electrically coupling a second electrode to the second conductive layer; and
electrically connecting the first electrode and the second electrode.

12. The method of claim 11, wherein forming the first conductive layer comprises solidifying a conductive polymerizable material on the first electrode.

13. The method of claim 11, wherein depositing the second conductive layer comprises electrochemically depositing the second conductive layer in the recesses and on the protrusions of the first conductive layer.

14. The method of claim 11, wherein depositing the second conductive layer comprises substantially filling the recesses such that the filled recesses are substantially without voids.

15. The method of claim 11, wherein forming the first conductive layer comprises forming a spacing of less than about 20 nm between the protrusions.

16. The method of claim 11, wherein forming the first conductive layer comprises forming the protrusions with a length of at least about 50 nm.

17. The method of claim 11, wherein forming the first conductive layer comprises forming the protrusions with a ratio of the length of the protrusions to the spacing between the protrusions of at least about 5.

18. The method of claim 11, wherein one of the electrodes reflects ultraviolet light and one of the electrodes is substantially transparent to ultraviolet light.

19. The method of claim 11, wherein the first conductive layer is an electron acceptor layer and the second conductive layer is an electron donor layer, or the first conductive layer is an electron donor layer and the second conductive layer is an electron acceptor layer.

20. The method of claim 19, wherein forming the first electrically conductive layer with a nano-imprint lithography process includes ultraviolet curing of an organic conductive polymer to form the electron donor layer.

21. A nano-imprint lithography method comprising:
forming patterned layer on a substrate, the patterned layer comprising a multiplicity of protrusions;
electrodepositing a conductive polymer on the patterned layer; and
dissolving the patterned layer to yield a conductive layer with a multiplicity of recesses, wherein the recesses are complementary to the protrusions of the patterned layer.
